(19) United States
(12) Patent Application Publication
(10) Pub. No.: US 2012/0223433 A1
(43) Pub. Date: Sep. 6, 2012

(54) SEMICONDUCTOR PACKAGE INCLUDING CONNECTING MEMBER HAVING CONTROLLED CONTENT RATIO OF GOLD

(76) Inventors: Young-kun Jee, Suwon-si (KR); Ji-hwan Hwang, Asan-si (KR); Kwang-chul Choi, Suwon-si (KR); Jung-hwan Kim, Bucheon-si (KR); Tae-hong Min, Gumi-si (KR)

(21) Appl. No.: 13/409,480

(22) Filed: Mar. 1, 2012

(30) Foreign Application Priority Data
Mar. 3, 2011 (KR) 10-2011-0019099

(51) Int. Cl. H01L 23/488

(52) U.S. Cl. 257/772; 257/E23.023

(57) ABSTRACT

A semiconductor package including connecting members having a controlled content ratio of gold capable of increasing durability and reliability by preventing an intermetallic compound having high brittleness from being formed. The semiconductor package includes a base substrate; a first semiconductor chip disposed on the base substrate; and a first connecting member for electrically connecting the base substrate and the first semiconductor chip, and comprising a first bonding portion that includes gold and has a first content ratio of gold that is controlled to prevent an intermetallic compound of AuSn₄, (Cu, Au)Sn₄, or (Ni, Au)Sn₄ from being formed.

### CROSS-REFERENCE TO RELATED PATENT APPLICATION

This application claims the benefit of Korean Patent Application No. 10-2011-0019099, filed on Mar. 3, 2011, in the Korean Intellectual Property Office, the disclosure of which is incorporated herein in its entirety by reference.

### BACKGROUND

The present disclosure relates to a semiconductor package, and more particularly, to a semiconductor package including a connecting member having a controlled content ratio of gold.

A semiconductor package is formed through a packaging process for a semiconductor chip. In the semiconductor package, a substrate and a set of one or more semiconductor chips mounted on the substrate generally connect to each other via an electrical connecting member such as a bonding wire or a solder ball, etc. Such an electrical connecting member includes various metal alloys, which can cause the formation of an intermetallic compound having high brittleness, and thus durability and reliability of the semiconductor package may deteriorate.

### SUMMARY

According to one embodiment, there is provided a semiconductor package including: a base substrate; a first semiconductor chip disposed on the base substrate; and a first connecting member for electrically connecting the base substrate and the first semiconductor chip, and comprising a first bonding portion that includes gold and has a first content ratio of gold that is controlled to prevent an intermetallic compound of AuSn₄, (Cu, Au)Sn₄, or (Ni, Au)Sn₄ from being formed.

In some embodiments, the first content ratio of gold may be in a range of 0.001% to 24.3%.

In some embodiments, the first bonding portion may include copper (Cu), tin (Sn), and gold (Au).

In some embodiments, the first bonding portion may have the first content ratio of gold in a range of 0.001% to 24.3% with respect to total content of copper (Cu), tin (Sn), and gold (Au).

In some embodiments, the first bonding portion may include an intermetallic compound of (Cu, Au)₆Sn₄.

In some embodiments, the intermetallic compound of (Cu, Au)₆Sn₄ may contain gold in the range of 0.001% to 24.3%.

In some embodiments, the first bonding portion may be a region in which formation of the intermetallic compound of (Cu, Au)₆Sn₄ is inhibited.

In some embodiments, the first content ratio of gold may be in a range of 0.001% to 4.6%.

In some embodiments, the first bonding portion may include nickel (Ni), tin (Sn), and gold (Au).

In some embodiments, the first bonding portion may have the first content ratio of gold in a range of 0.001% to 4.6% with respect to total content of nickel (Ni), tin (Sn), and gold (Au).

In some embodiments, the first bonding portion may include an intermetallic compound of (Ni, Au)₃Sn₄.

In some embodiments, the intermetallic compound of (Ni, Au)₃Sn₄ may contain gold in a range of 0.001% to 4.6%.

In some embodiments, the first bonding portion is a region in which formation of the intermetallic compound of (Ni, Au)Sn₄ may be inhibited.

In some embodiments, the first bonding member may include a bottom pillar and a top pillar, and the first bonding portion may be disposed between the bottom pillar and the top pillar.

In some embodiments, the bottom pillar, the top pillar, or both of them may contain copper (Cu), nickel (Ni), or an alloy thereof.

In some embodiments, the semiconductor package may further include: a second semiconductor chip disposed on the first semiconductor chip; and a second connecting member for electrically connecting the first semiconductor chip and the second semiconductor chip, and including a second bonding portion having a second content ratio of gold that is controlled to prevent the intermetallic compound of AuSn₄, (Cu, Au)Sn₄, or (Ni, Au)Sn₄ from being formed in the second connecting member.

In some embodiments, first semiconductor chip may include through silicon vias (TSVs) that are electrically connected to the second bonding portion.

In some embodiments, the TSVs may be electrically connected to the first bonding portion.

According to some embodiments, there is provided a semiconductor device including: a first substrate; a second substrate disposed on the first substrate; and at least a first conductive interconnection physically and electrically connecting the first substrate and the second substrate. The first conductive interconnection may include: a first portion including at least one of nickel (Ni) or copper (Cu), a bonding portion including gold, and an interface formed at a boundary between the first portion and the bonding portion, the interface including a first compound including one or more of AuSn4, (Cu, Au)Sn4, and (Ni, Au)Sn4, and a second compound different from the first compound, wherein a mole fraction of the first compound to the combination of the first compound and the second compound is less than 5%.

In some embodiments, the content ratio of gold in the bonding portion is in a range of 0.001% to 24.3%.

In some embodiments, the bonding portion includes a solder material.

In some embodiments, the first substrate is one of a package substrate and a semiconductor chip substrate; and the second substrate is a semiconductor chip substrate.

In some embodiments the second compound includes at least one of (Cu, Au)6Sn5, or (Ni, Au)3Sn4.

In some embodiments, the semiconductor device includes: a conductive pad at the surface of the first substrate and connected to the first conductive interconnection; and a conductive pad at the surface of the second substrate and connected to the first conductive interconnection.

According to some embodiments, there is provided a conductive interconnection disposed between a first substrate and a second substrate of a semiconductor device. The conductive interconnection includes: a top portion comprising a first conductive material; a bottom portion comprising a second conductive material; and a middle bonding portion disposed between the top portion and the bottom portion and comprising a third conductive material, the middle bonding portion including gold. A content ratio of gold for the middle bonding portion may be below 24.3%, and an amount of an intermetallic compound including one of AuSn4, (Cu, Au)Sn4, or (Ni, Au)Sn4 formed in the middle bonding portion may be substantially zero.

According to some embodiments, the top portion is connected to a semiconductor chip disposed above the conductive interconnection; and the bottom portion is connected to a semiconductor chip or a package substrate disposed below the conductive interconnection.

### BRIEF DESCRIPTION OF THE DRAWINGS

Exemplary embodiments will be more clearly understood from the following detailed description taken in conjunction with the accompanying drawings in which:

FIG. 1 is a cross-sectional view of a semiconductor package according to an exemplary embodiment;

FIG. 2 is a cross-sectional view of a semiconductor package according to another exemplary embodiment;

FIG. 3 is a cross-sectional view of a semiconductor package according to a further exemplary embodiment;

FIGS. 4 through 6 are cross-sectional views illustrating an exemplary method of forming connecting members included in semiconductor packages according to one embodiment;

FIGS. 7 through 11 are exemplary binary phase diagrams of elements included in connecting members of semiconductor packages according to certain embodiments;

FIGS. 12 and 13 are scanning electron microscope (SEM) photos showing a difference in an interface between copper and tin with respect to the content of gold after a drop test of 300 cycles is performed according to exemplary embodiments

FIG. 14 is a schematic block diagram of an exemplary memory card according to one embodiment;

FIG. 15 is a schematic block diagram of an exemplary system according to one embodiment; and

FIG. 16 is a perspective view of an exemplary electronic device to which semiconductor devices manufactured according to certain disclosed embodiments are applicable.

### DETAILED DESCRIPTION OF THE EMBODIMENTS

Reference will now be made in detail to exemplary embodiments, examples of which are illustrated in the accompanying drawings. However, exemplary embodiments are not limited to the embodiments illustrated hereinafter, and the embodiments herein are rather introduced to provide a comprehensive understanding of the scope and spirit of the disclosure. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the exemplary embodiments. As used herein, the singular forms “a,” “an” and “the” are intended to include the plural forms as well, unless the context clearly indicates otherwise. It will be further understood that the terms “comprises,” “comprising,” “includes,” and “including,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of the exemplary embodiments (and intermediate structures). As such, variations from the shapes of the illustrations as a result, for example, of manufacturing techniques and/or tolerances, are to be expected. Thus, the exemplary embodiments should not be construed as being limited to the particular shapes of regions illustrated herein but may include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes and are not intended to limit the scope of the exemplary embodiments.

Unless otherwise defined, all terms (including technical and scientific terms) used herein have the same meaning as commonly understood by one of ordinary skill in the art to which the exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

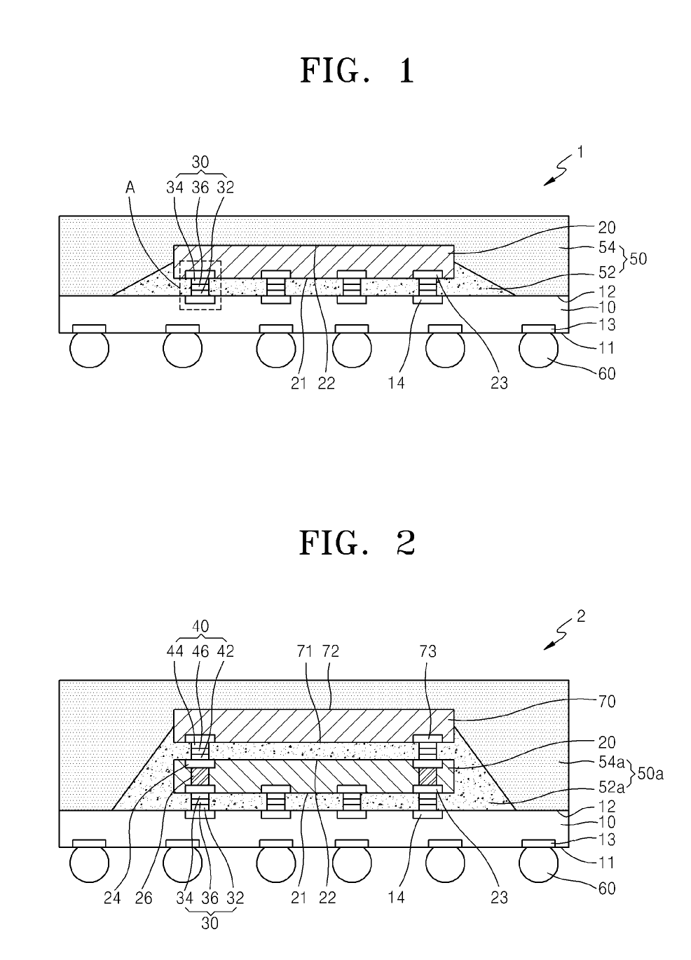

FIG. 1 is a cross-sectional view of a semiconductor package 1 according to an exemplary embodiment.

Referring to FIG. 1, the semiconductor package 1 includes a base substrate 10, a first semiconductor chip 20, and first connecting members 30. The semiconductor package 1 may optionally include a molding member 50 and/or external connecting members 60.

The base substrate 10 may be formed, for example, of glass, ceramic, or plastic. The base substrate 10 may be a semiconductor package substrate, for example, a printed circuit board, a ceramic substrate, or a tape wiring substrate. Bottom pads 13 may be disposed on a bottom surface 11 of the base substrate 10, and top pads 14 may be disposed on a top surface 12 thereof. The bottom pads 13 and the top pads 14 may include conductive materials, for example, metal, such as aluminum (Al), copper (Cu), gold (Au), silver (Ag), chromium (Cr), palladium (Pd), or an alloy thereof. The base substrate 10 may further include wires (not shown) that electrically connect the bottom pads 13 and the top pads 14 therein and transfer voltages and/or signals between semiconductor chips mounted on the base substrate 10 and an external board or device. Sizes or pitches of the top pads 14 may be smaller than sizes or pitches of the bottom pads 13. In this case, the wires may function as re-wiring patterns. However, the relative sizes or pitches between the bottom pads 13 and the top pads 14 are exemplary, and the disclosure is not limited thereto.

The first semiconductor chip 20 is disposed on the base substrate 10. The first semiconductor chip 20 may be, for example, a logic semiconductor chip or a memory semiconductor chip. The logic semiconductor chip may be a micro-processor, for example, a central processing unit (CPU), a controller, or an application specific integrated circuit (ASIC), or the like. The memory semiconductor chip may be a volatile memory, such as dynamic random access memories (DRAM) or static random access memory (SRAM), or a nonvolatile memory, such as flash memory. Although one first semiconductor chip 20 is shown in FIG. 1, the disclosure is not limited thereto. For example, the first semiconductor chip 20 may be configured to include a plurality of semiconductor chips that may be the same type or different types. For example, the first semiconductor chip 20 may be a combination of one or more logic semiconductor chips and one or more memory semiconductor chips. In addition, one or more of the semiconductor chips may be different sizes, and the semiconductor chips may be stacked in different arrangements (i.e., vertically aligned, zig-zag, spiral-shaped, mesa shaped, etc.).

The first semiconductor chip 20 may include a bottom surface 21 neighboring but spaced apart from the base substrate 10 and a top surface 22 further spaced apart from the base substrate 10 with respect to the bottom surface 21. The first semiconductor chip 20 may include a chip substrate having circuitry, such as an integrated circuit, formed thereon. In one embodiment, the bottom surface 21 may be an active layer in which electronic devices are formed. However, the disclosure is not limited as such, and in another embodiment, the active layer may be formed on the top surface 22 or is buried within the first semiconductor chip 20. The bottom pads 23 may be disposed at the bottom surface 21. The bottom pads 23 may include conductive materials, for example, metal, such as aluminum (Al), copper (Cu), gold (Au), tin (Sn), chromium (Cr), palladium (Pd), or an alloy thereof

The first connecting members 30, also referred to herein as conductive interconnections, may be disposed to electrically and/or physically connect the base substrate 10 and the first semiconductor chip 20. Thus, the first connecting members 30 may provide electrical connecting paths between the base substrate 10 and the first semiconductor chip 20. For example, the top pads 14 of the base substrate 10 and the bottom pads 23 of the first semiconductor chip 20 may be electrically connected to one another through the first connecting members 30. The first connecting members 30 may be controlled to prevent an intermetallic compound having high brittleness from being formed. The first connecting members 30 may have a flip-chip connection structure including a pin grid array, a ball grid array, and a land grid array. Alternatively, the first connecting members 30 may include solder balls.

The first connecting members 30 may include a bottom pillar 32 (also referred to as a bottom portion) that by itself or together with a bottom pad 23 comprises a bottom terminal, a top pillar 34 (also referred to as a top portion) that by itself or together with a top pad 14 comprises a top terminal, and a first bonding portion 36 that comprises a middle portion disposed between the bottom pillar 32 and the top pillar 34. The bottom pillar 32, the top pillar 34, or both of them may include a conductive material, for example, copper (Cu), nickel (Ni), or an alloy thereof

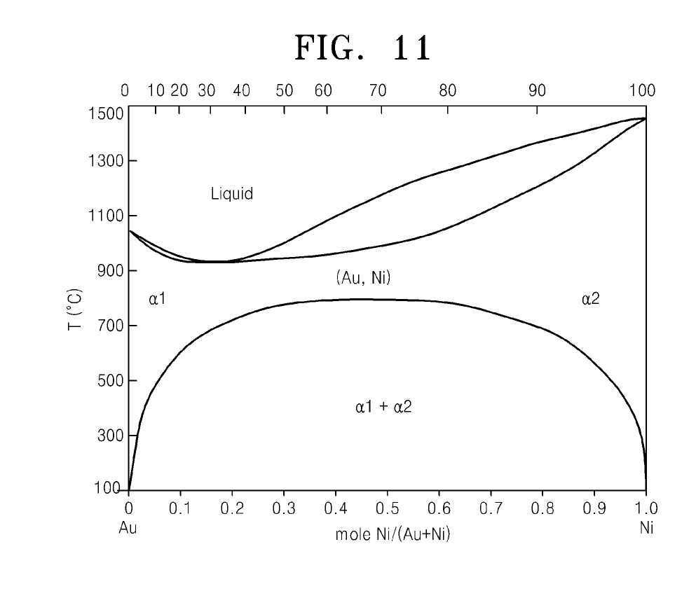

The first bonding portion 36 may be controlled to prevent the intermetallic compound having the high brittleness from being formed. For example, the first bonding portion 36 may have a first content ratio of gold that is controlled to prevent an intermetallic compound of AuSn₄ and/or an intermetallic compound of (Cu, Au)Sn₄ and/or an intermetallic compound of (Ni, Au)Sn₄ from being formed. In one embodiment as described herein, the intermetallic compound is a compound formed at the boundary between the bonding portion 36 formed of a first material, for example, of tin (Sn), and a pillar (e.g., 32), formed of a second material, for example, copper (Cu) or nickel (Ni). An example of an intermetallic compound is shown in FIG. 12 as (Cu, Au)₆Sn₅. The first bonding portion 36 may therefore include a body portion that does not include the intermetallic compound or only includes trace amounts, and a boundary portion, or interface, that includes significant amounts of the intermetallic compound.

One or more intermetallic compounds may be formed at a boundary portion of a first bonding portion 36. In one embodiment, only a first compound, such as (Cu, Au)₆Sn₅ is formed, and no second compound, such as AuSn₄, (Cu, Au)Sn₄, or (Ni, Au)Sn₄ is formed at the boundary portion. In another embodiment, both the first compound and the second compound are formed at the boundary portion, but a ratio, such as a mole fraction, of the second compound to the combination of the first compound and the second compound is small enough (e.g. less than 5%) to prevent cracking or brittleness at the boundary typically caused by the second compound. As such, the amount or content ratio of the second compound with respect with respect to the first bonding portion 36 may be substantially zero, so that it has zero or only an insignificant effect on the brittleness and/or cracking at the boundary.

The first bonding portion 36 may include, for example, copper (Cu), tin (Sn), gold (Au), or an alloy thereof. In this case, the first content ratio of gold in the first bonding portion 36 may be, for example, below 30% (e.g., between 0.001% and 24.3%), with respect to the total material included in the first bonding portion 36. As such, an atomic percent of gold in the first bonding portion 36 (the ratio of gold atoms to total atoms in the first bonding portion 36) may have one of these ratios. In addition, because this ratio is maintained, an amount of any of AuSN₄, (Cu, Au)Sn₄, (Ni, Au)Sn₄ in the first bonding portion 36 may be substantially zero.

For example, in one embodiment, the first bonding portion 36 may have the first content ratio of gold, for example, between 0.001% and 24.3%, with respect to total content of copper (Cu), tin (Sn), and gold (Au). The first bonding portion 36 may be a region in which the formation of the intermetallic compound of AuSn₄ and/or the intermetallic compound of (Cu, Au)Sn₄ is prevented.

The first bonding portion 36 may include, for example, an intermetallic compound of Cu₆Sn₅ and/or an intermetallic compound of (Cu, Au)₆Sn₅. The first bonding portion 36 may not include the intermetallic compound of AuSn₄ and/or the intermetallic compound of (Cu, Au)Sn₄, or may include only an insignificant amount of such compounds. In one embodiment, the intermetallic compound of AuSn₄ and/or the intermetallic compound of (Cu, Au)Sn₄ having relatively high brittleness are not formed in the first bonding portion 36 or are formed only in insignificant amounts to prevent cracking and high brittleness, but the intermetallic compound of Cu₆Sn₅ and/or the intermetallic compound of (Cu, Au)₆Sn₅ having relatively low brittleness may be formed therein. To this end, the first bonding portion 36 including the intermetallic compound of (Cu, Au)₆Sn₅ may include gold, for example, having a content ratio below between 0.001% and 24.3%. If the first bonding portion 36 including the intermetallic compound of (Cu, Au)₆Sn₅ includes gold, for example, greater than 24.3%, gold may be discharged from the intermetallic compound of (Cu, Au)₆Sn₅ to form the intermetallic compound of AuSn₄ and/or the intermetallic compound of (Cu, Au)Sn₄, which may be undesirable. Therefore, gold may be included in bonding portion 36, but the content ratio of gold in the bonding portion 36 may be maintained below 24.3%.

The first bonding portion 36 may further include silver (Ag). In one embodiment, the first bonding portion 36 may include gold, for example, between 0.001% and 24.3%, with respect to the remaining content excluding silver. For example, the ratio of number of atoms of gold to the number of atoms of total materials excluding silver (Ag) (i.e. the total content of copper (Cu), tin (Sn), and gold (Au)) may be between 0.001% and 24.3%.

In certain embodiments, the first bonding portion 36 may include nickel (Ni), tin (Sn), gold (Au), or an alloy thereof. In this case, the first content ratio of gold may be, for example, below 5% (e.g., between 0.001% and 4.6%), with respect to the total material included in the first bonding portion 36.

The first bonding portion 36 may include the first content ratio of gold, for example, between 0.001% and 4.6%, with respect to the total content of copper (Cu), tin (Sn), and gold (Ag). The first bonding portion 36 may be a region in which the formation of the intermetallic compound of AuSn₄ and/or the intermetallic compound of (Ni, Au)Sn₄ is prevented.

In one embodiment, the first bonding portion 36 may include an intermetallic compound of Ni₃Sn₄ and/or an intermetallic compound of (Ni, Au)₃Sn₄. In addition, the first bonding portion 36 may be prevented from including the intermetallic compound of AuSn₄ and/or the intermetallic compound of (Ni, Au)Sn₄, or may include only an insignificant amount of such material so as to have a zero or negligible effect on the brittleness of the first bonding portion 36. That is, the intermetallic compound of AuSn₄ and/or the intermetallic compound of (Ni, Au)Sn₄ having relatively high brittleness are not formed in the first bonding portion 36 or are formed to have substantially zero concentration so as to have a zero or negligible effect on the brittleness or cracking of the first bonding portion 36, but the intermetallic compound of Ni₃Sn₄ and/or the intermetallic compound of (Ni, Au)₃Sn₄ having relatively low brittleness may be formed therein. To this end, the intermetallic compound of (Ni, Au)₃Sn₄ may include gold, for example, having a content ratio between 0.001% and 4.6% with respect to the first bonding portion 36. If the intermetallic compound of (Ni, Au)₃Sn₄ includes gold, for example, having a content ratio with respect to the first bonding portion that is greater than 4.6%, gold may be discharged from the intermetallic compound of (Ni, Au)₃Sn₄ to form the intermetallic compound of AuSn₄ and/or the intermetallic compound of (Ni, Au)Sn₄, which may be undesirable. Therefore, gold may be included in bonding portion 36, but the content ratio of gold may be maintained below 4.6%.

The first bonding portion 36 may further include silver (Ag). In this case, the first bonding portion 36 may include gold, for example, between 0.001% and 4.6%, with respect to the remaining content excluding silver, i.e. the total content of nickel (Ni), tin (Sn), and gold (Ag).

In one embodiment, the first semiconductor chip 20 is sealed by the molding member, such as mold 50, and accordingly may be protected from the outside. The mold 50 may include, for example, an underfill portion 52 disposed below the first semiconductor chip 20, and filling a space between the first connecting members 30, and a lateral side molding portion 54 which is disposed on the underfill portion 52 and seals the lateral sides and a top of the first semiconductor chip 20. The mold 50 may be formed in a molded underfill (MUF) manner. The mold 50 may include an insulation material, such as, for example, a resin. The underfill member 52 and the lateral side molding member 54 may include the same material or different materials.

The external connecting members 60 may be disposed on the bottom pads 13 of the base substrate 10 to be electrically and/or physically connected to the bottom pads 13. The base substrate 10 may be electrically connected to the outside through the external connecting members 60. Thus, the semiconductor package 20 may be electrically connected to the outside through the external connecting members 60. The external connecting members 60 may be, for example, solder balls or bumps. Alternatively, the external connecting members 60 may have a flip-chip connection structure including a pin grid array, a ball grid array, and a land grid array.

The intermetallic compound of (Cu, Au)₆Sn₅ endures a high load, has a high destructive resistance, and low brittleness compared to the intermetallic compound of AuSn₄. Thus, the intermetallic compound of (Cu, Au)₆Sn₅ may provide high durability and high mechanical stability compared to the intermetallic compound of AuSn₄. Therefore, by preventing the formation of AuSn₄ and/or maintaining a concentration of AuSn₄ at negligible, substantially zero levels such that significant cracking is prevented, the first bonding portion 36 can have a low brittleness and still benefit from the advantages of including gold.

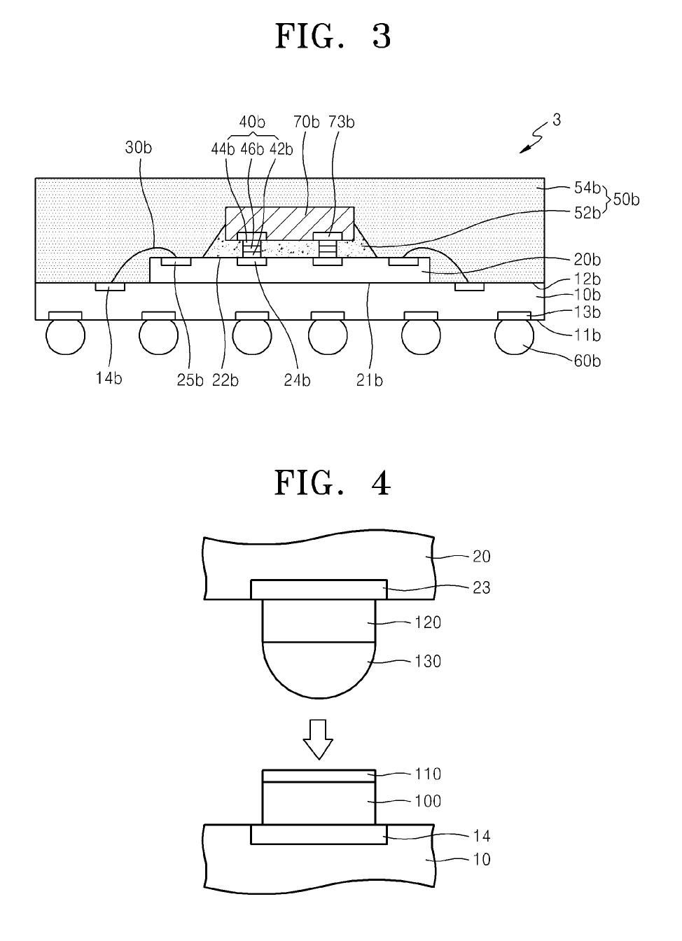

FIG. 2 is a cross-sectional view of a semiconductor package 2 according to another exemplary embodiment. The semiconductor package 2 of FIG. 2 includes stacked semiconductor chips compared to the semiconductor package 1 of FIG. 1. Redundant descriptions between FIGS. 1 and 2 will not be repeated here.

Referring to FIG. 2, the semiconductor package 2 includes the base substrate 10, the first semiconductor chip 20, and the first connecting members 30 that electrically connect the base substrate 10 and the first semiconductor chip 20. The semiconductor package 2 includes a second semiconductor chip 70 and second connecting members 40 that electrically connect the first semiconductor chip 20 and the second semiconductor chip 70.

The first semiconductor chip 20 may be disposed on the base substrate 10. The first semiconductor chip 20 may include the bottom pads 23 at the bottom surface 21 and the top pads 24 at the top surface 22. The first semiconductor chip 20 and the base substrate 10 may be electrically connected to each other through the first connecting members 30. The first connecting members 30 may include the bottom pillar 32, the top pillar 34, and the first bonding portion 36 disposed between the bottom pillar 32 and the top pillar 34. The first bonding portion 36 may be controlled to prevent an intermetallic compound having high brittleness from being formed. For example, the first bonding portion 36 may have a first content ratio of gold that is controlled to prevent an intermetallic compound of AuSn₄, an intermetallic compound of (Cu, Au)Sn₄, and/or an intermetallic compound of (Ni, Au)Sn₄ from being formed.

The first semiconductor chip 20 may include through substrate vias, such as through silicon vias (TSVs) 26 that penetrate therethrough. The TSVs 26 may electrically connect the bottom pads 23 and the top pads 24. That is, the TSVs 26 may provide electrical connecting paths between the bottom pads 23 and the top pads 24. The TSVs 26 may have a multilayer structure in which, for example, an insulating layer (not shown), a seed layer (not shown), and a conductive layer (not shown) may be sequentially formed. The TSVs 26 may include, for example, one or more selected from the group consisting of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium(Pd), platinum (Pt), rhodium (Rh), rhenium (Re), lutetium (Ru), tantalum (Ta), tellurium (Te), titanium (Ti), tungsten (W), zinc (Zn), and zirconium (Zr). The TSVs 26 may be formed, for example, by using chemical vapor deposition (CVD), plasma enhanced CVD (PECVD), high-density plasma CVD (HDP-CVD), sputtering, metal organic CVD (MOCVD), or atomic layer deposition (ALD). The TSVs may pass through the entire first semiconductor chip 20, or through a portion of first semiconductor chip 20.

The second semiconductor chip 70 may be disposed on the first semiconductor chip 20. The second semiconductor chip 70 may be a logic semiconductor chip or a memory semiconductor chip as described above. For example, although one second semiconductor chip 70 is shown in FIG. 2, the inventive concept is not limited thereto. For example, the second semiconductor chip 70 may be configured to include a plurality of semiconductor chips that may be the same type or different types. For example, the second semiconductor chip 70 may be a combination of one or more logic semiconductor chips and one or more memory semiconductor chips. The first semiconductor chip 20 and the second semiconductor chip 70 may be a combination of one or more logic semiconductor chips and one or more memory semiconductor chips. For example, the first semiconductor chip 20 may be a logic semiconductor chip, and the second semiconductor chip 70 may be a memory semiconductor chip, or vice versa.

The second semiconductor chip 70 may include a bottom surface 71 spaced apart from and neighboring the first semiconductor chip 20 and a top surface 72 further spaced apart from the first semiconductor chip 20 with respect to the bottom surface 71. The bottom surface 71 may be an active layer in which electronic devices are formed. Alternatively, the active layer may be formed on the top surface 72 or may be buried in the second semiconductor chip 70 according to the certain embodiments. The bottom pads 73 may be disposed in the bottom surface 71 of the second semiconductor chip 70. The bottom pads 73 may include conductive materials, for example, metal, such as aluminum (Al), copper (Cu), gold (Au), tin (Sn), chromium (Cr), palladium (Pd), or an alloy thereof.

The second connecting members 40 may electrically connect the first semiconductor chip 20 and the second semiconductor chip 70. For example, the top pads 24 of the first semiconductor chip 20 and the bottom pads 73 of the second semiconductor chip 70 may be electrically connected to one another through the second connecting members 40. The second connecting members 40 may be controlled to prevent an intermetallic compound having high brittleness from being formed. The second connecting members 40 may have a flip-chip connection structure including a pin grid array, a ball grid array, and a land grid array. Alternatively, the second connecting members 40 may be solder balls.

The second connecting members 40 may include a bottom pillar 42, a top pillar 44, and a second bonding portion 46 disposed between the bottom pillar 42 and the top pillar 44. The bottom pillar 42, the top pillar 44, or both of them may include a conductive material, for example, copper (Cu), nickel (Ni), or an alloy thereof. The second bonding portion 46 may be controlled to prevent the intermetallic compound having the high brittleness from being formed. For example, the second bonding portion 46 may have a second content ratio of gold that is controlled to prevent an intermetallic compound of AuSn₄, an intermetallic compound of (Cu, Au)Sn₄, and/or an intermetallic compound of (Ni, Au)Sn₄ from being formed.

In one embodiment, the second bonding portion 46 may include copper (Cu), tin (Sn), gold (Au), or an alloy thereof. In this case, the second content ratio of gold may be, for example, below 30% (e.g., between 0.001% and 24.3%), with respect to the total material included in the second bonding portion 46.

In another embodiment, the second bonding portion 46 may include nickel (Ni), tin (Sn), gold (Au), or an alloy thereof. In this case, the second content ratio of gold may be, for example, below 5% (e.g., between 0.001% and 4.6%), with respect to the total material included in the second bonding portion 46.

The second bonding portion 46 may correspond to the first bonding portion 36 described with reference to FIG. 1, and thus a detailed description thereof will be omitted here. The second content ratio of gold of the second bonding portion 46 may the same as or different from the first content ratio of gold of the first bonding portion 36. The TSVs 26 may be electrically connected to the first bonding portion 36 and the second bonding portion 46.

The first semiconductor chip 20 and the second semiconductor chip 70 may be sealed by a molding member 50a, and accordingly may be protected from the outside. The molding member 50a may include an underfill portion 52a disposed below the first semiconductor chip 20, and filling a space between the first connecting members 30, and a lateral side molding portion 54a which is disposed on the underfill portion 52a and seals the top and lateral side of the first semiconductor chip 20. The underfill portion 52a may fill the second connecting members 70 disposed below the second semiconductor chip 70. The lateral side molding portion 54a may seal the lateral side of the second semiconductor chip 70.

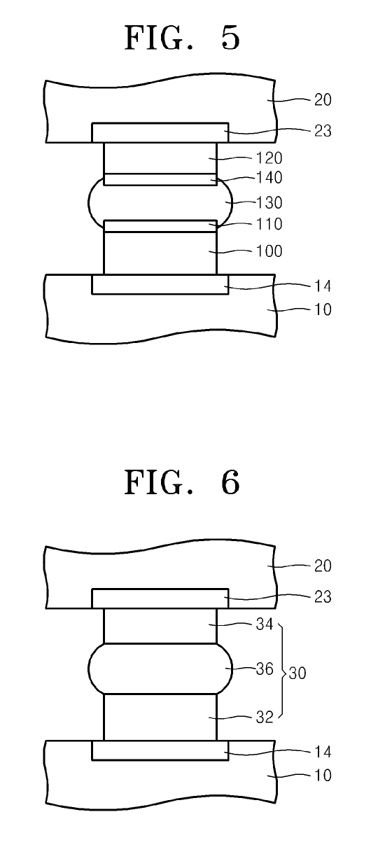

FIG. 3 is a cross-sectional view of a semiconductor package 3 according to a further exemplary embodiment. The semiconductor package 3 of FIG. 3 includes stacked semiconductor chips of which one is electrically connected to a base substrate through a bonding wire different from the semiconductor packages 1 and 2 of FIGS. 1 and 2. Redundant descriptions between FIGS. 1 through 3 will not be repeated here.

Referring to FIG. 3, the semiconductor package 3 includes a base substrate 10b, a first semiconductor chip 20b, and a bonding wire 30b that electrically connects the base substrate 10b and the first semiconductor chip 20b. The semiconductor package 3 includes a second semiconductor chip 70b and first connecting members 40b that electrically connect the first semiconductor chip 20b and the second semiconductor chip 70b.

The base substrate 10b may include bottom pads 13b that are electrically connected to external connecting members 60b and top pads 14b that are electrically connected to the first semiconductor chip 20b.

The first semiconductor chip 20b may be disposed on the base substrate 10b.

The first semiconductor chip 20b may be a logic semiconductor chip or a memory semiconductor chip as described above. The first semiconductor chip 20b may include a bottom surface 21b adhered to the base substrate 10b and a top surface 22b facing the bottom surface 21b. The bottom surface 21b of the first semiconductor chip 20b may be adhered to the base substrate 10b by using an adhesive member (not shown) such as, for example, a liquid adhesive, a solid adhesive, or a bonding tape. As such, connecting members such as discussed above in connection with FIGS. 1 and 2 may not be included between first semiconductor chip 20b and base substrate 10b. The top surface 22b of the first semiconductor chip 20b may include first top pads 24b and second top pads 25b. The top pads 25b of the first semiconductor chip 20b may be electrically connected to the top pads 14b of the base substrate 10b through the bonding wire 30b.

The second semiconductor chip 60b may be disposed on the first semiconductor chip 20b. The second semiconductor chip 70b may be a logic semiconductor chip or a memory semiconductor chip as described above. Third pads 73b may be disposed on a bottom surface of the second semiconductor chip 70b.

The first connecting members 40b may electrically connect the first semiconductor chip 20b and the second semiconductor chip 70b. For example, the first top pads 24b of the first semiconductor chip 20b and the third pads 73b of the second semiconductor chip 70b may be electrically connected to one another through the first connecting members 40b. The first connecting members 40b may be controlled to prevent an intermetallic compound having high brittleness from being formed. The first connecting members 40b may include, for example, solder balls or bumps. Alternatively, the first connecting members 40b may have a flip-chip connection structure including a pin grid array, a ball grid array, and a land grid array. The first connecting members 40b may include a bottom pillar 42b, a top pillar 44b, and a first bonding portion 46b disposed between the bottom pillar 42b and the top pillar 44b.

The first connecting members 40b may be controlled to prevent the intermetallic compound having the high brittleness from being formed. For example, the first connecting members 40b may have a content ratio of gold that is controlled to prevent an intermetallic compound of AuSn₄, an intermetallic compound of (Cu, Au)Sn₄, and/or an intermetallic compound of (Ni, Au)Sn₄ from being formed.

In one embodiment, the first connecting members 40b may include copper (Cu), tin (Sn), gold (Au), or an alloy thereof. In this case, the content ratio of gold of the first bonding portions 46b of first connecting members 40b may be, for example, below 30% (e.g., between 0.001% and 24.3%), with respect to the total material included in the first bonding portions 46b of connecting members 40b.

In another embodiment, the first connecting members 40b may include nickel (Ni), tin (Sn), gold (Au), or an alloy thereof. In this case, the content ratio of gold of the first bonding portions 46b of first connecting members 40b may be, for example, below 5% (e.g., between 0.001% and 4.6%), with respect to the total material included in the first bonding portions 46b of first connecting members 40b.

The first connecting members 40b may correspond to the connecting members 30 or 40 described with reference to FIGS. 1 and 2, respectively, and thus a detailed description thereof will be omitted here.

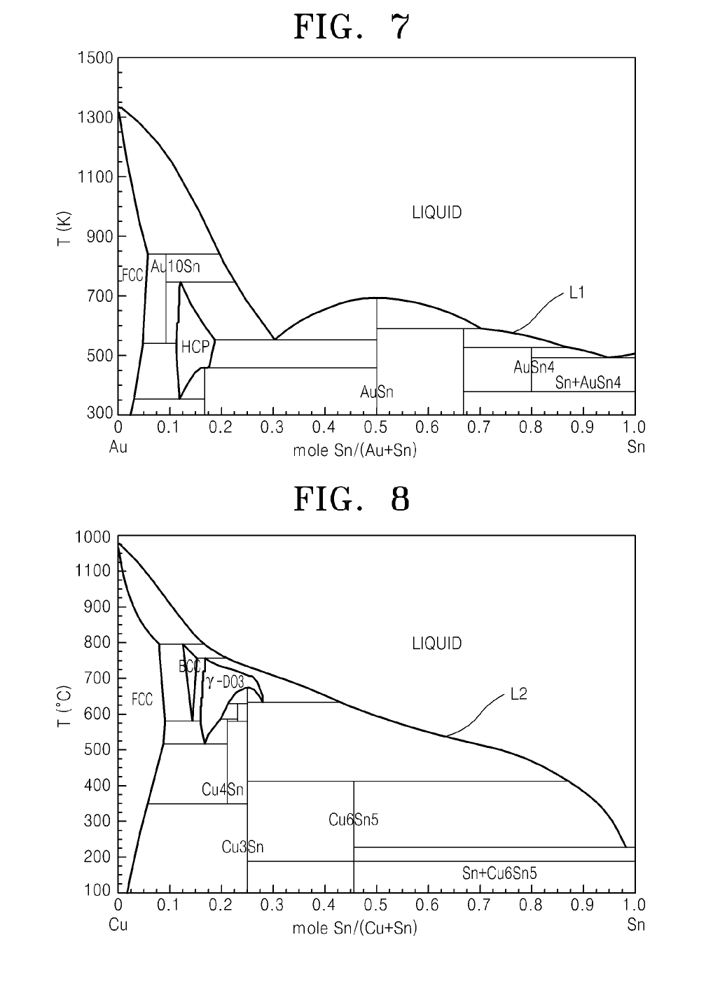

FIGS. 4 through 6 are cross-sectional views illustrating an exemplary method of forming connecting members included in semiconductor packages according to certain exemplary embodiments. A process of forming a region A of FIG. 1 is described with reference to FIGS. 4 through 6. The process may be applied to the connecting members 40 of FIG. 2 and the connecting members 40b of FIG. 3 in the same manner. The connecting members shown in FIGS. 4 through 6 may be part of different semiconductor devices. For example, they may be part of the semiconductor package discussed with regard to FIGS. 1 through 3 above, part of a package-on-package semiconductor package, part of a stack of semiconductor chips connected to a memory module or other module, etc.

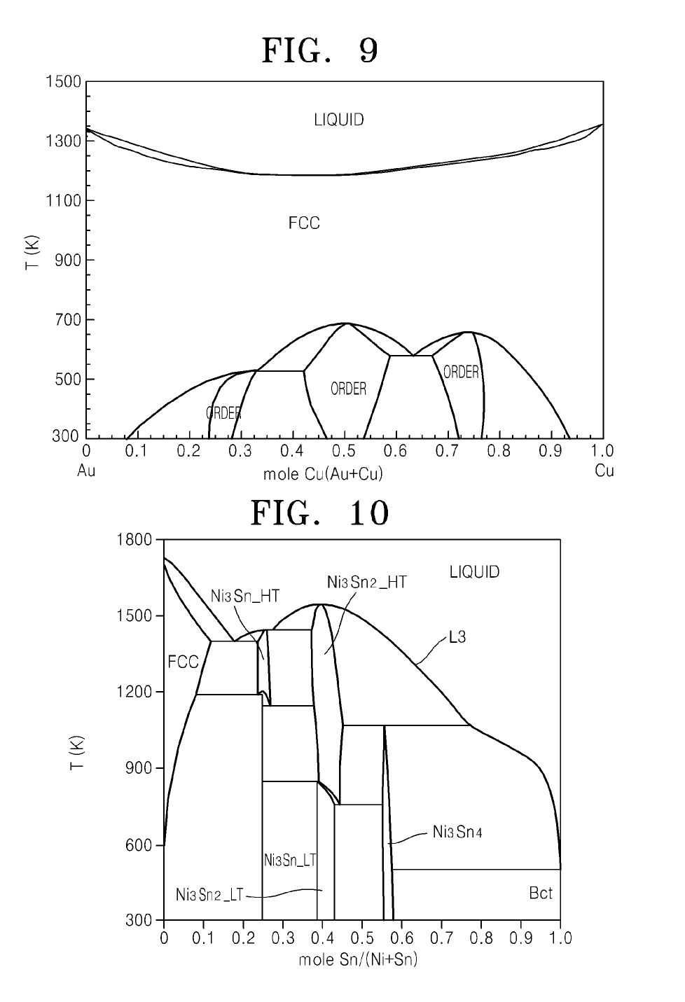

FIGS. 7 through 11 are binary phase diagrams of elements included in connecting members of semiconductor packages according to some embodiments. FIG. 7 is a binary phase diagram of gold and tin, FIG. 8 is a binary phase diagram of copper and tin, FIG. 9 is a binary phase diagram of gold and copper, FIG. 10 is a binary phase diagram of nickel and tin, and FIG. 11 is a binary phase diagram of gold and nickel. The binary phase diagrams of FIGS. 7 through 11 are used to describe reactions between elements included in connecting members such as the first connecting members 30, for example, copper, tin, gold and/or nickel, which occur while the processes of FIG. 4 through 6 are performed.

Referring to FIG. 4, the top pad 14 may be disposed on the top surface 12 of the base substrate 10, and the bottom pad 23 may be disposed on a bottom surface of the first semiconductor chip 20. The top pad 14 and bottom pad 23 may each connect, for example, to additional wiring within the base substrate 10 and first semiconductor chip 20 respectively. The wiring may electrically connect to circuitry such as, for example, transistors, capacitors, etc., and/or may serve as redistribution lines in certain cases. A bottom protrusion portion 100 including a conductive material is formed on the top pad 14. The bottom protrusion portion 100 may be, for example, a terminal providing an electrical and physical connection between the base substrate 10 and another substrate, such as a substrate that forms first semiconductor chip 20. A contact layer 110 is formed on the bottom protrusion portion 100. The contact layer 110 may be formed of a material that increases wettability between materials. In one embodiment, a thickness of the contact layer 110 is be maintained so as to inhibit an intermetallic compound that is not desired in a final structure from being formed. A top protrusion portion 120 including a conductive material is formed on the bottom pad 23. The top protrusion portion 120 may be, for example, a terminal providing an electrical and physical connection between the first semiconductor chip 20 and another substrate, such as a the base substrate 10. A solder layer 130 is formed on the top protrusion portion 120. The solder layer 130 may include metal having a relatively low melting point. The contact layer 110 and the solder layer 130 may be formed, for example, by using a photolithography method, a plating method, or a pressing method.

A case where the bottom protrusion portion 100 and the top protrusion portion 120 include copper, the contact layer 110 includes gold, and the solder layer 130 includes tin will now be described. However, this is merely exemplary, and the disclosure is not limited thereto.

The base substrate 10 and the first semiconductor chip 20 physically and electrically connect to each other. For example, in one embodiment, the contact layer 110 and the solder layer 130 physically contact each other, and the solder layer 130 is then dissolved by applying appropriate pressure and temperature.

Referring to FIG. 5, the solder layer 130 is formed to have a relatively low melting point and thus is liquidized at a low temperature. For example, if the solder layer 130 is formed of pure tin, a melting point of the solder layer 130 is 232° C. (or 505 K).

After the solder layer 130 melts, the contact layer 110 is dissolved in the melted solder layer 130. For example, if the contact layer 110 is formed of pure gold, the contact layer 110 has a relatively high melting point of 1064° C. (or 1337 K). However, referring to FIG. 7, which is the binary phase diagram of gold and tin, if the content of tin included in the solder layer 130 is relatively greater than the content of gold included in the contact layer 110, gold may be dissolved at a temperature closer to the melting point of tin. For example, if the amount of gold is 20% (for example, if a mole fraction of gold is 20%), gold may be wholly mixed with tin and be liquidized at a temperature of about 290° C. (or 563 K). If gold is 50% (for example, the mole fraction is 50%), gold may be wholly mixed with tin and be liquidized at a temperature of about 427° C. (or 700 K). As described above, to prevent the intermetallic compound of AuSn₄ from being formed, in one embodiment, a process condition whereby a temperature is maintained higher than a temperature for forming the intermetallic compound of AuSn₄ should be used, such as a process condition whereby a temperature is maintained higher than a gold-tin liquid line L1 in the binary phase diagram of gold and tin of FIG. 7. In some embodiments, since the content of tin included in the solder layer 130 is greater than the content of gold included in the contact layer 110, if tin is dissolved, gold may be wholly dissolved at a temperature closer to a melting point of tin. A tin-gold reaction is a liquid phase reaction, which may be the fastest compared to other reactions.

Thereafter, copper included in the bottom protrusion portion 100 and the top protrusion portion 120 diffuses toward the solder layer 130 and forms a boundary layer 140. Such a tin-copper reaction is a liquid-solid phase diffusion reaction which occurs later than the tin-gold reaction. Referring to the binary phase diagram of copper and tin of FIG. 8, although a melting point of copper is 1085° C. (1358 K), it is lowered at a region having much tin. Copper starts dissolving in a liquid of tin (actually, a mixture liquid of tin and gold), and reaches a copper-tin liquid line L2 in FIG. 8. Then a solid phase of copper-tin is formed, for example, an intermetallic compound of Cu₆Sn₅. That is, the boundary layer 140 may include an intermetallic compound of copper and tin, for example, the intermetallic compound of Cu₆Sn₅.

Thereafter, copper included in the intermetallic compound of Cu₆Sn₅ is substituted by gold, and thus an intermetallic compound of (Cu, Au)₆Sn₅ is formed. Such a copper-gold substitution reaction occurs in a solid phase, which occurs later than the above reactions and has a slow reaction speed. Gold substitutes copper, and thus the intermetallic compound of (Cu, Au)₆Sn₅ continuously grows toward the liquid of tin-gold, which increases the boundary layer 140. In some cases, the boundary layer 140 may grow until the solder layer 130 disappears. Referring to the binary phase diagram of gold and copper of FIG. 9, gold and copper form an isomorphous solid solution of a face centered cubic (FCC) structure in almost entire region independent of temperature and form order lattices in some regions at room temperature. In addition, gold and copper do not form an intermetallic compound. Therefore, any intermetallic compound including gold and copper having different shapes are not formed in the boundary layer 140, and thus the intermetallic compound of (Cu, Au)₆Sn₅ may stably exist. However, if the content of gold exceeds a stable range in the intermetallic compound of (Cu, Au)₆Sn₅, gold is discharged from the intermetallic compound of (Cu, Au)₆Sn₅, or gold in a liquid phase no longer goes through the substitution reaction, and accordingly remains, thereby forming the intermetallic compound of AuSn₄ and/or the intermetallic compound of (Cu, Au)Sn₄ that is not desired. Therefore, it is important to control a content ratio of gold so as to prevent the intermetallic compound from being formed.

Referring to FIG. 6, the boundary layer 140 is solidified and thus the first bonding portion 36 is formed. The bottom protrusion portion 100 and the top protrusion portion 120 form the first pillar 32 and the second pillar 34, respectively. The first bonding portion 36 may have a boundary portion and a body portion, and may have a content ratio of gold that is controlled to prevent the intermetallic compound of AuSn₄ and/or the intermetallic compound of (Cu, Au)Sn₄ from being formed, as described above. A thickness of the contact layer 110 prior to melting may be determined to implement the controlled content ratio of gold in the resulting first bonding portion 36 shown in FIG. 6.

The content ratio of gold may be, for example, below 30% (e.g., between 0.001% and 24.3%), with respect to the total material included in the first bonding portion 36. For example, the content ratio of gold may be, for example, between 0.001% and 24.3%, with respect to the total content of copper, tin, and gold. For example, the first bonding portion 36 may include the intermetallic compound of (Cu, Au)₆Sn₅. The intermetallic compound of (Cu, Au)₆Sn₅ may include gold, for example, between 0.001% and 24.3%.

A case where the bottom protrusion portion 100 and the top protrusion portion 120 include nickel, the contact layer 110 includes gold, and the solder layer 130 includes tin will now be described.

The process described with reference to FIG. 4 is performed to physically contact the base substrate 10 and the first semiconductor chip 20 to each other, and dissolving the solder layer 130 by applying appropriate pressure and temperature.

Thereafter, as described with reference to FIGS. 5 and 7, since the solder layer 130 has a low melting point, the solder layer 130 is liquidized at a low temperature, and the contact layer 110 is dissolved in the melted solder layer 130 and thus the tin-gold liquid phase is formed.

Thereafter, nickel included in the bottom protrusion portion 100 and the top protrusion portion 120 diffuses forward the solder layer 130 and forms the boundary layer 140. Referring to the binary phase diagram of nickel and tin of FIG. 10, although a melting point of nickel is 1455° C. (1728 K), it is lowered at a region having much tin. Nickel starts dissolving in a liquid of tin (actually, a mixture liquid of tin and gold), and reaches a nickel-tin liquid line L3. Then a solid phase of nickel-tin is formed, for example, an intermetallic compound of Ni₃Sn₄. The boundary layer 140 may thus include an intermetallic compound of nickel and tin, for example, the intermetallic compound of Ni₃Sn₄. Although such a nickel-tin reaction is similar to the copper-tin region stated above, since the nickel-tin liquid line L3 in the region having much tin (i.e. on the right) is further inclined (i.e., steeper) compared to the copper-tin liquid line L2, the intermetallic compound of Ni₃Sn₄ in the nickel-tin liquid line L3 shown in FIG. 10 may occur earlier and have a faster growth speed than in the copper-tin liquid line L2 shown in FIG. 8.

Thereafter, nickel included in the intermetallic compound of Ni₃Sn₄ is substituted by gold, and thus an intermetallic compound of (Ni, Au)₃Sn₄ is formed. Gold substitutes nickel, and thus the intermetallic compound of (Ni, Au)₃Sn₄ continuously grows toward the liquid of tin-gold, which increases the boundary layer 140. In some cases, the boundary layer 140 may grow until the solder layer 130 disappears. Furthermore, referring to the binary phase diagram of gold and nickel of FIG. 11, two phases, a1 and a2, separately exist at room temperature, and thus the content of gold that can substitute nickel is very small. This is related to the content of gold being restricted to below 5%.

Thereafter, as described with reference to FIG. 6, the boundary layer 140 is solidified and thus the first bonding portion 36 is formed. The first bonding portion 36 may have a content ratio of gold that is controlled to prevent the intermetallic compound of AuSn₄ and/or the intermetallic compound of (Ni, Au)Sn₄ from being formed as described above. A thickness of the contact layer 110 may be determined to implement the controlled content ratio of gold.

The content ratio of gold may be, for example, below 5% (e.g., between 0.001% and 4.6%), with respect to the total material included in the first bonding portion 36. For example, the content ratio of gold may be, for example, between 0.001% and 4.6%, with respect to the total content of nickel, tin, and gold. The first bonding portion 36 may include the intermetallic compound of (Ni, Au)₃Sn₄. The intermetallic compound of (Ni, Au)₃Sn₄ may include gold, for example, between 0.001 at % and 4.6 at %.

FIGS. 12 and 13 are scanning electron microscope (SEM) photos showing a difference in an interface between copper and tin with respect to the content of gold after a drop test of 300 cycles is performed according to certain embodiments. In FIG. 12, the content of gold included in an intermetallic compound of Cu₆Sn₅ is 10%. In FIG. 13, the content of gold included in the intermetallic compound of Cu₆Sn₅ is 30%.

Referring to FIG. 12, an intermetallic compound of (Cu, Au)₆Sn₅ is discovered in the interface between copper and tin, and no cracks are apparent therein. This occurs in part because no AuSn₄ or (Cu, Au)Sn₄, or only an insignificant amount thereof, is formed, which reduces the brittleness of the connecting members, leaving no noticeable cracks.

Referring to FIG. 13, an intermetallic compound of (Cu, Au)₆Sn₅ is discovered in an interface neighboring copper, an intermetallic compound of AuSn₄ is discovered in an interface neighboring tin, and a crack is apparent therein since the intermetallic compound of AuSn₄ is destroyed.

Such results are due to high brittleness of the intermetallic compound of AuSn₄. Thus, the intermetallic compound of Cu₆Sn₅ including gold of 10% has an interface stability higher than the intermetallic compound of Cu₆Sn₅ including gold of 30%, which provides an increased durability and reliability of the semiconductor package.

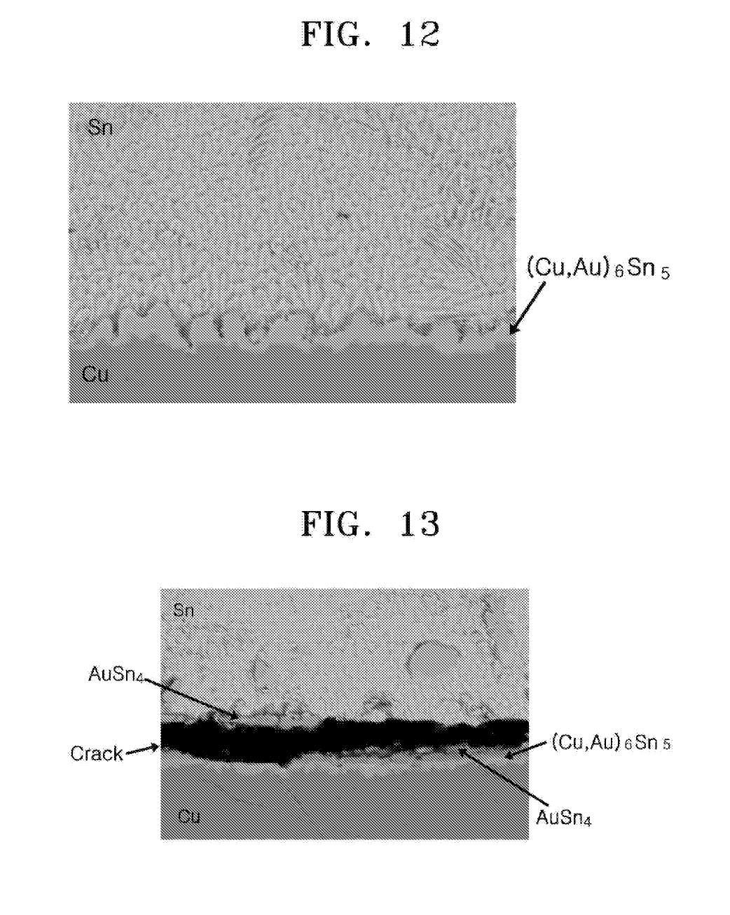

FIG. 14 is a schematic block diagram of a card 5000 according to an exemplary embodiment.

Referring to FIG. 14, a controller 5100 and a memory 5200 may be arranged to exchange electrical signals with each other. For example, when a command is issued by the controller 5100, the memory 5200 may transmit data. The controller 5100 and/or the memory 5200 may include a semiconductor package according to any one of the embodiments described above. The memory 5200 may include a memory array (not shown) or a memory array bank (not shown). The card 5000 may be used in a memory device such as a memory card, for example, a memory stick card, a smart media (SM) card, a secure digital (SD) card, a mini SD card, or a multi media card (MMC).

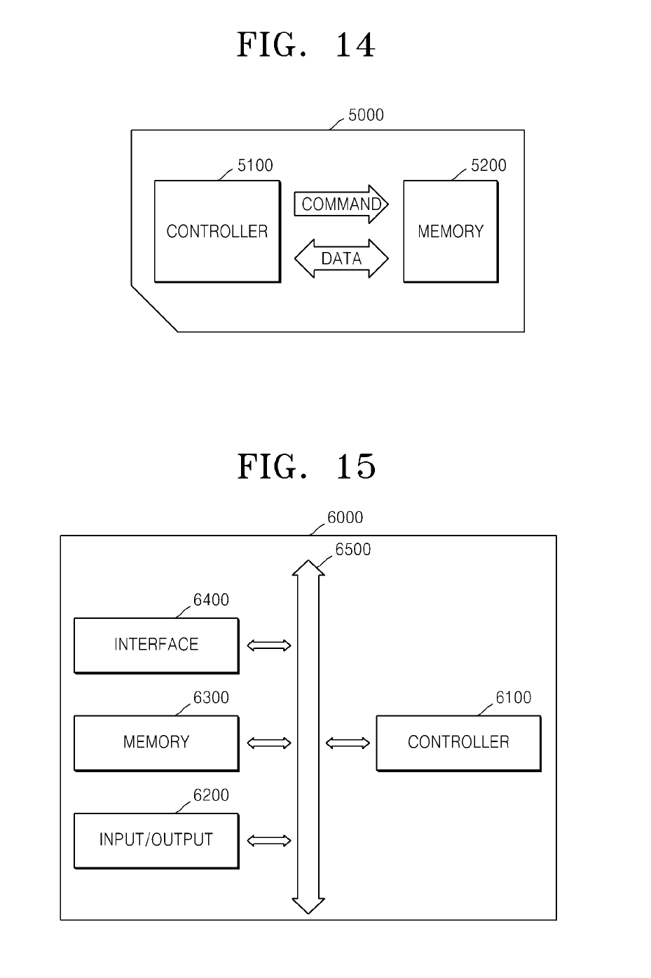

FIG. 15 is a schematic block diagram of a system 6000 according to another exemplary embodiment.

Referring to FIG. 15, the system 6000 may include a controller 6100, an input/output (I/O) device 6200, a memory 6300, and an interface 6400. The system 6000 may be, for example, a mobile system that transmits or receives information. The mobile system may be a PDA, a portable computer, a web tablet, a wireless phone, a mobile phone, a digital music player, or a memory card, for example. The controller 6100 may execute a program and control the system 6000. The controller 6100 may be a microprocessor, a digital signal processor, a microcontroller, or a device similar to these devices. The I/O device 6200 may be used to input or output the data of the system 6000. The system 6000 may be connected to an external device, for example, a personal computer or a network, by using the I/O device 6200, and thus may exchange data with the external device. The I/O device 6200 may be a keypad, a keyboard, or a display. The memory 6300 may store code and/or data for operating the controller 6100, and/or store data processed by the controller 6100. The controller 6100 and the memory 6300 may include a semiconductor package according to any one of the embodiments described above. The interface 6400 may be a data transmission path between the system 6000 and another external device. The controller 6100, the I/O device 6200, the memory 6300, and the interface 6400 may communicate with each other via a bus 6500. For example, the system 6000 may be used in a mobile phone, an MP3 player, a navigation system, a portable multimedia player (PMP), a solid state disk (SSD), or household appliances.

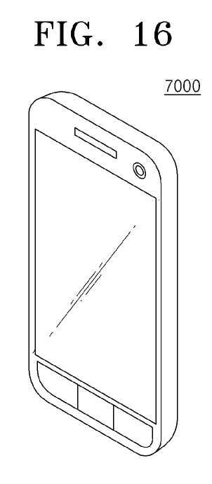

FIG. 16 is a perspective view of an exemplary electronic device to which semiconductor devices manufactured according to the disclosed embodiments are applicable.

FIG. 16 illustrates a mobile phone 7000 to which the electronic system 6000 of FIG. 15 may be applied. The electronic system 6000 of FIG. 15 may also be used in portable notebooks, MP3 players, navigation, SSDs, cars, household appliances, and the like.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed is:

1. A semiconductor package comprising:
a base substrate;
a first semiconductor chip disposed on the base substrate; and
a first connecting member for electrically connecting the base substrate and the first semiconductor chip, and comprising a first bonding portion that includes gold and has a first content ratio of gold that is controlled to prevent an intermetallic compound of AuSn₄, (Cu, Au)Sn₄, or (Ni, Au)Sn₄ from being formed.

2. The semiconductor package of claim 1, wherein the first content ratio of gold is in a range of 0.001% to 24.3%.

3. The semiconductor package of claim 1, wherein the first bonding portion comprises copper (Cu), tin (Sn), and gold (Au).

4. The semiconductor package of claim 3, wherein the first bonding portion has the first content ratio of gold in a range of 0.001% to 24.3% with respect to total content of copper (Cu), tin (Sn), and gold (Au).

5. The semiconductor package of claim 1, wherein the first bonding portion comprises an intermetallic compound of (Cu, Au)₆Sn₅.

6. The semiconductor package of claim 5, wherein the intermetallic compound of (Cu, Au)₆Sn₅ contains gold in the range of 0.001% to 24.3%.

7. The semiconductor package of claim 1, wherein the first content ratio of gold is in a range of 0.001% to 4.6%.

8. The semiconductor package of claim 1, wherein the first bonding portion comprises nickel (Ni), tin (Sn), and gold (Au).

9. The semiconductor package of claim 8, wherein the first bonding portion has the first content ratio of gold in a range of 0.001% to 4.6% with respect to total content of nickel (Ni), tin (Sn), and gold (Au).

10. The semiconductor package of claim 1, wherein the first bonding portion comprises an intermetallic compound of (Ni, Au)₃Sn₄.

11. The semiconductor package of claim 10, wherein the intermetallic compound of (Ni, Au)₃Sn₄ contains gold in a range of 0.001% to 4.6%.

12. The semiconductor package of claim 1, further comprising:
a second semiconductor chip disposed on the first semiconductor chip; and
a second connecting member for electrically connecting the first semiconductor chip and the second semiconductor chip, and comprising a second bonding portion having a second content ratio of gold that is controlled to prevent the intermetallic compound of AuSn₄, (Cu, Au)Sn₄, or (Ni, Au)Sn₄ from being formed in the second connecting member.

13. A semiconductor device comprising:
a first substrate;
a second substrate disposed on the first substrate; and
at least a first conductive interconnection physically and electrically connecting the first substrate and the second substrate,
wherein the first conductive interconnection includes:
a first portion including at least one of nickel (Ni) or copper (Cu),
a bonding portion including gold, and
an interface formed at a boundary between the first portion and the bonding portion, the interface including a first compound including one or more of AuSn₄, (Cu, Au)Sn₄, and (Ni, Au)Sn₄, and a second compound different from the first compound, wherein a mole fraction of the first compound to the combination of the first compound and the second compound is less than 5%.

14. The semiconductor device of claim 13, wherein the content ratio of gold in the bonding portion is in a range of 0.001% to 24.3%.

15. The semiconductor device of claim 13, wherein the bonding portion includes a solder material.

16. The semiconductor device of claim 13, wherein:
the first substrate is one of a package substrate and a semiconductor chip substrate; and
the second substrate is a semiconductor chip substrate.

17. The semiconductor device of claim 13, wherein:
the second compound includes at least one of (Cu, Au)₆Sn₅, or (Ni, Au)₃Sn₄.

18. The semiconductor device of claim 13, further comprising:
a conductive pad at the surface of the first substrate and connected to the first conductive interconnection; and
a conductive pad at the surface of the second substrate and connected to the first conductive interconnection.

19. A conductive interconnection disposed between a first substrate and a second substrate of a semiconductor device, the conductive interconnection including:
a top portion comprising a first conductive material;
a bottom portion comprising a second conductive material; and
a middle bonding portion disposed between the top portion and the bottom portion and comprising a third conductive material, the middle bonding portion including gold,
wherein a content ratio of gold for the middle bonding portion is below 24.3%, and
wherein an amount of an intermetallic compound including one of AuSn₄, (Cu, Au)Sn₄, or (Ni, Au)Sn₄ formed in the middle bonding portion is substantially zero.

20. The conductive interconnection of claim 19, wherein:
the top portion is connected to a semiconductor chip disposed above the conductive interconnection; and
the bottom portion is connected to a semiconductor chip or a package substrate disposed below the conductive interconnection.
